(19) United States
(12) Patent Application Publication
(10) Pub. No.: US 2012/0146452 A1
(43) Pub. Date: Jun. 14, 2012

(54) MICROELECTROMECHANICAL SYSTEM DEVICE AND SEMI-MANUFACTURE AND MANUFACTURING METHOD THEREOF

(75) Inventors: HUA-SHU WU, HSINCHU CITY (TW); SHIH-YUNG CHUNG, HSINCHU COUNTY (TW); YU-HAO CHIEN, TAIPEI CITY (TW); LI-TIEN TSENG, TAOYUANG COUNTY (TW); YU-TE YEH, TAICHUNG COUNTY (TW)

(73) Assignee: MIRADIA, INC., SANTA CLARA, CA (US)

(21) Appl. No.: 13/296,366

(22) Filed: Nov. 15, 2011

Related U.S. Application Data
(60) Provisional application No. 61/421,786, filed on Dec. 10, 2010.

(51) Int. Cl. H02N 1/00; H01L 21/02

(52) U.S. Cl. 310/300; 438/15; 257/E21.002; 257/417

(57) ABSTRACT

A manufacturing method of the MEMS device disposes a conductive circuit to maintain various elements of the MEMS equi-potential thereby preventing electrostatic damages to various elements of the MEMS during the manufacturing process.

### CROSS-REFERENCE TO RELATED APPLICATIONS

This application claims the benefit of the U.S. Provisional Patent Application Ser. No. 61/421,786, filed Dec. 10, 2010, currently pending, entitled “Microelectromechanical System Device and Semi-manufacture and Manufacturing Method thereof”; the contents of which are hereby incorporated by reference.

### BACKGROUND OF THE INVENTION

1. Field of the Invention

The present invention relates to a MEMS device and the semi-manufacture and manufacturing method thereof, and more particularly to a MEMS device and the semi-manufacture and manufacturing method thereof that prevent electrostatic damages to the elements during the manufacturing process.

2. Description of the Prior Art

A Microelectromechanical System (MEMS) device including a movable element achieves various functions of the MEMS device by sensing or controlling the physical quantity of the movement of the movable element. However, in a manufacturing process of the MEMS device, such as dry etching, ion implantation, and mechanical grinding, etc., the elements of the MEMS device may be charged, and the electrostatic forces may cause stiction between the elements and/or distortion of the elements. It is therefore highly desirable to prevent the elements of the MEMS device from being damaged by electrostatic forces during the manufacturing process.

### SUMMARY OF THE INVENTION

The present invention is directed to a MEMS device and the semi-manufacture and manufacturing method thereof that maintain various elements of the MEMS to be equi-potential by using a conductive circuit, thereby preventing electrostatic damages to the elements of the MEMS during the manufacturing process.

According to an embodiment, the semi-manufacture of the MEMS device includes a substrate, a MEMS and a conductive circuit. The MEMS is disposed on the substrate and includes a movable element and a functional element. The functional element is coupled with the movable element for sensing a physical quantity of movement of the movable element and outputting a corresponding sensed signal, or controlling the movable element to generate the desired physical quantity of movement. The conductive circuit is disposed on the substrate and electrically connected with the movable element and the functional element so that the movable element and the functional element are equi-potential.

According to another embodiment, the manufacturing method of the MEMS device includes: providing a substrate; disposing a MEMS and a conductive circuit on the substrate, wherein the MEMS includes a movable element and a functional element, wherein the functional element is coupled with the movable element for sensing the physical quantity of movement of the movable element and outputting a corresponding sensed signal, or controlling the movable element to generate a desired physical quantity of movement, and the conductive circuit is electrically connected with the movable element and the functional element so that the movable element and the functional element are equi-potential; and disconnecting the conductive circuit.

According to another embodiment, the MEMS device includes: a substrate, a movable element, a functional element and a conductive circuit. The movable element is disposed on the substrate. The functional element is disposed on the substrate, coupled with the movable element for sensing a physical quantity of movement of the movable element and outputting a corresponding sensed signal, or controlling the movable element to generate the desired physical quantity of movement. The conductive circuit is disposed on the substrate and includes a switch circuit. The conductive circuit is electrically connected with the movable element and the functional element so that when the switch circuit is conductive or cutoff the movable element and the functional element are equi-potential or electrically isolated.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed description, in conjunction with the accompanying drawings, wherein:

FIG. 1 is a schematic top view diagram illustrating the semi-manufacture of the MEMS device according to an embodiment of the present invention;

FIG. 2 is a schematic top view diagram illustrating the semi-manufacture of the MEMS device according to another embodiment of the present invention; and

FIG. 3 is a flow chart illustrating a manufacturing method of the MEMS device according to an embodiment of the present invention.

### DESCRIPTION OF THE PREFERRED EMBODIMENT

The detailed explanation of the present invention is described as follows. The described preferred embodiments are presented for purposes of illustrations and description, and they are not intended to limit the scope of the present invention.

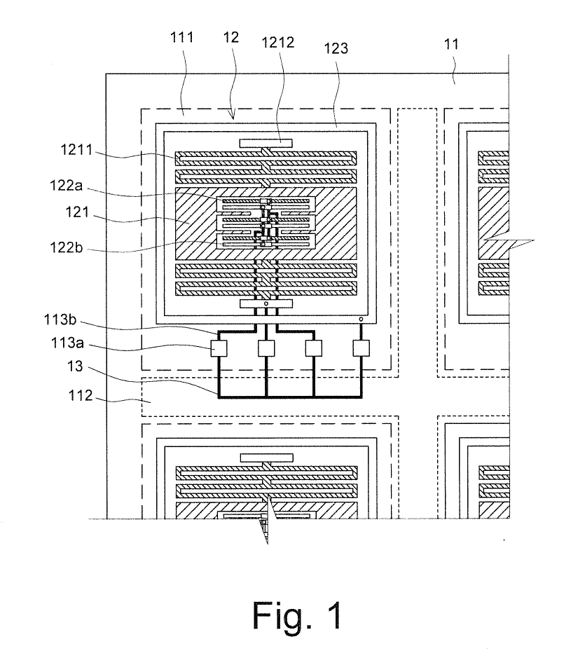

Referring to FIG. 1, there is illustrated a Y-axis accelerometer as an example for the semi-manufacture of the MEMS device according to an embodiment. The semi-manufacture of the MEMS device illustrated in FIG. 1 includes a substrate 11, a MEMS 12 and a conductive circuit 13. The substrate 11 includes a MEMS configuration area 111 and a scribe line area 112. The substrate 11 may be made of a semiconductor material, glass or the combination thereof. A plurality of MEMSs 12 are disposed in the MEMS configuration area 111 of the substrate 11, and may be separated into individual MEMSs 12 after sawing.

The MEMS 12 includes a movable element 121 and a functional element. As illustrated in FIG. 1, the two sides of the movable element 121 along the direction of the Y axis respectively connect with elastic elements 1211, and the other side of each elastic element 1211 is connected with the substrate 11 through an anchor 1212. In such way, the movable element 121 may move along the direction of the Y axis. According to the embodiment illustrated in FIG. 1, the functional element may include a first sensor 122a and a second sensor 122b. The first sensor 122a and the second sensor 122b are coupled with the movable element 121 to sense the physical quantity of movement of the movable element 121 and output a corresponding sensed signal. By via or eutectic bonding technology, such as Al—Ge eutetic bonding, the movable element 121 and the functional element can be electrically connected to traces 113b and conductive contacts 113a and the MEMS 12 may then be able to transmit the sensed signal through the conductive contacts 113a to the outside. It is noted that in other embodiments, the functional element may also control the movable element to generate a desired physical quantity of movement to realize different functions of MEMS devices.

Referring still to FIG. 1, the conductive circuit 13 is disposed on the substrate 11, and is electrically connected with the movable element 121 and the functional element of the MEMS 12. Since the conductive circuit 13 connects the movable element 121 and the functional element electrically, during the manufacturing process of the MEMS 12 or the MEMS device, the movable element 121 and the functional element are maintained equi-potential, thereby preventing the movable element 121 and the functional element to stick to each other or to be distorted due to electrostatic forces. According to an embodiment, the conductive circuit 13 is disposed in the scribe line area 112 of the substrate 11. Hence, when the substrate 11 is sawed to separate MEMSs 12, the conductive circuit 13 would be destroyed thereby electrically isolating the movable element 121 and the functional element.

According to an embodiment, the MEMS 12 may include a guard ring 123 surrounding the movable element 121 and the functional element. Normally speaking, the guard ring 123 is grounded. By the same token, the conductive circuit 13 may also be connected with the guard ring 123 to maintain the guard ring 123, the movable element 121 and the functional element equi-potential during the manufacturing process.

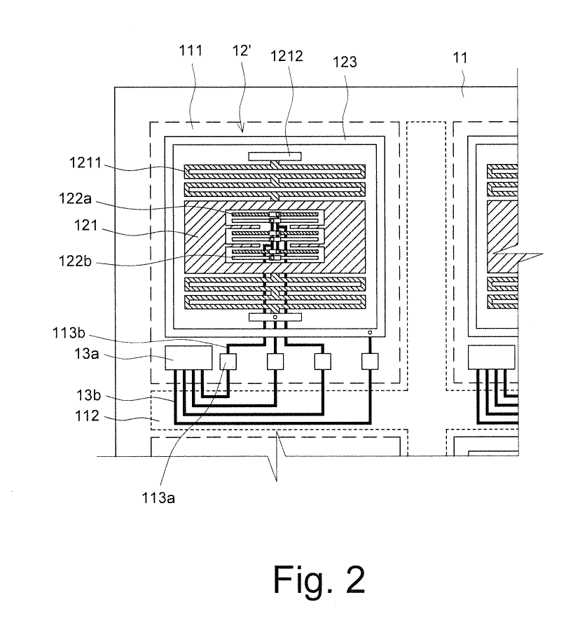

Referring to FIG. 2, according to an embodiment, the conductive circuit may include a switch circuit 13a, and the switch circuit 13a is electrically connected with the elements of the MEMS 12 through traces 13b. The switch circuit 13a may be controlled conducting or cutoff arbitrarily by a user. According to this embodiment, the switch circuit 13a may be controlled conducting during the manufacturing process to maintain those elements of the MEMS 12 electrically connected with the conductive circuit equi-potential, and cutoff during testing of the MEMS to keep those elements electrically isolated. According to an embodiment, the conductive circuit may be integrated in the MEMS 12′, i.e. the conductive circuit is disposed in the MEMS configuration area 111 of the substrate 11.

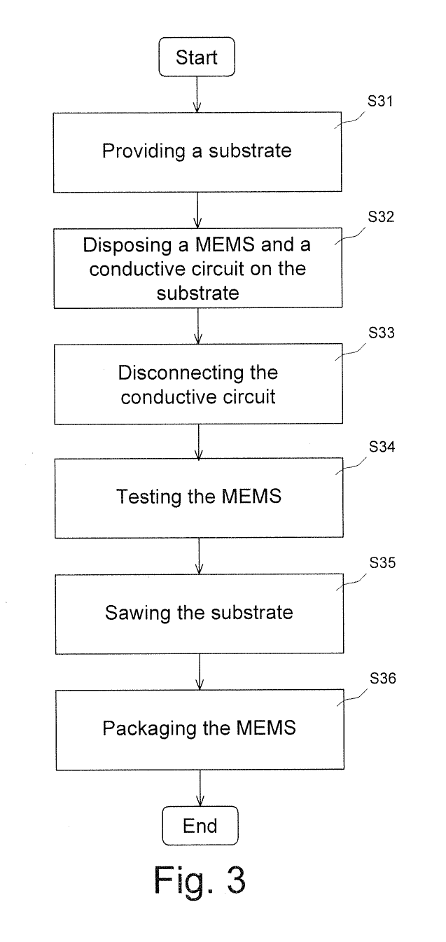

Referring to FIG. 3, there is illustrated a manufacturing method of the MEMS device according to an embodiment. First a substrate is provided (S31); then, a MEMS and a conductive circuit are disposed on the substrate (S32). The structure of the MEMS is described above and would be omitted here. During the manufacturing process, the conductive circuit is electrically connected with the movable element and the functional element of the MEMS, so that the movable element and the functional element of the MEMS are equi-potential during the manufacturing process. After the manufacture of the MEMS is completed, or the manufacture of the whole MEMS device is completed, the conductive circuit can be disconnected (S33) so that the movable element and functional element of the MEMS are electrically isolated. The step of disconnecting the conductive circuit may be done when the substrate is sawed (S35), and then the MEMS may be packaged (S36).

It is noted that partial sawing (i.e. without cutting the substrate completely) or using the laser to destroy the conductive circuit 13, or employing the switch circuit to disconnect the conductive circuit may also be able to isolate the movable element and the functional element electrically. This way, a wafer-level test of the MEMS may be conducted (S34). Thereafter, the processes of substrate sawing (S35) and packaging of the MEMS (S36) may be performed.

To summarize the foregoing description, according to the present invention, the MEMS device and the semi-manufacture and the manufacturing method thereof exploits the existing processes, by disposing a conductive circuit to maintain various elements of the MEMS equi-potential during the manufacturing process, to prevent stiction and distortion damages to various elements of the MEMS due to electrostatic forces.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A semi-manufacture of a MEMS device, comprising:
a substrate;
a MEMS disposed on the substrate and comprising:
a movable element; and
a functional element coupled with the movable element for sensing a physical quantity of movement of the movable element and outputting a corresponding sensed signal, or controlling the movable element to generate the desired physical quantity of movement; and
a conductive circuit disposed on the substrate and electrically connected with the movable element and the functional element so that the movable element and the functional element are equi-potential.

2. The semi-manufacture of the MEMS device according to claim 1, wherein the MEMS further comprises a guard ring surrounding the movable element and the functional element.

3. The semi-manufacture of the MEMS device according to claim 2, wherein the conductive circuit and the guard ring are electrically connected.

4. The semi-manufacture of the MEMS device according to claim 1, wherein the substrate comprises a scribe line area, and the conductive circuit is disposed in the scribe line area.

5. The semi-manufacture of the MEMS device according to claim 1, wherein the conductive circuit is integrated in the MEMS.

6. The semi-manufacture of the MEMS device according to claim 1, wherein the conductive circuit comprises a switch circuit and controllably conducts or cutoff.

7. The semi-manufacture of the MEMS device according to claim 1, wherein the substrate comprises a semiconductor material, glass or the combination thereof.

8. A manufacturing method of the MEMS device, comprising:
providing a substrate;
disposing a MEMS and a conductive circuit on the substrate, wherein the MEMS comprises a movable element and a functional element, wherein the functional element is coupled with the movable element for sensing a physical quantity of movement of the movable element and outputting a corresponding sensed signal, or controlling the movable element to generate the desired physical quantity of movement; the conductive circuit is electrically connected with the movable element and the functional element so that the movable element and the functional element are equi-potential; and
disconnecting the conductive circuit.

9. The manufacturing method of the MEMS device according to claim 8, wherein the MEMS further comprises a guard ring surrounding the movable element and the functional element.

10. The manufacturing method of the MEMS device according to claim 9, wherein the conductive circuit and the guard ring are electrically connected.

11. The manufacturing method of the MEMS device according to claim 8, wherein the substrate comprises a scribe line area, and the conductive circuit is disposed in the scribe line area.

12. The manufacturing method of the MEMS device according to claim 8, wherein the conductive circuit is disconnected by sawing or laser.

13. The manufacturing method of the MEMS device according to claim 8, wherein the conductive circuit is integrated in the MEMS.

14. The manufacturing method of the MEMS device according to claim 8, wherein the conductive circuit comprises a switch circuit and controllably conducts or cutoff.

15. The manufacturing method of the MEMS device according to claim 8, further comprising:
testing the MEMS.

16. The manufacturing method of the MEMS device according to claim 8, further comprising:
sawing the substrate; and
packaging the MEMS.

17. The manufacturing method of the MEMS device according to claim 8, wherein the substrate comprises a semiconductor material, glass or the combination thereof.

18. A MEMS device, comprising:
a substrate;
a movable element disposed on the substrate; and
a functional element disposed on the substrate, coupled with the movable element for sensing a physical quantity of movement of the movable element and outputting a corresponding sensed signal, or controlling the movable element to generate the desired physical quantity of movement; and
a conductive circuit disposed on the substrate, comprising a switch circuit and electrically connected with the movable element and the functional element so that when the switch circuit is conductive or cutoff the movable element and the functional element are equi-potential or electrically isolated.

19. The MEMS device according to claim 18, wherein the MEMS further comprises a guard ring surrounding the movable element and the functional element.

20. The MEMS device according to claim 19, wherein the conductive circuit and the guard ring are electrically connected.
